(19) United States
(12) Patent Application Publication
(10) Pub. No.: US 2003/0112747 A1
(43) Pub. Date: Jun. 19, 2003

(54) Packet transmitter unit, packet receiver unit and packet transmission system

(76) Inventors: Kuniyuki Suzuki, Tokyo (JP); Michiaki Takano, Tokyo (JP); Takuya Yamazaki, Tokyo (JP); Nobuo Fujihara, Tokyo (JP); Minoru Abe, Tokyo (JP); Jingsong Duan, Tokyo (JP); Nobuyasu Yamaguchi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/239,860

(22) PCT Filed: Feb. 13, 2001
(86) PCT No.: PCT/JP01/00984

(51) Int. Cl. G08C 15/00; H04L 12/26; G06F 11/00; H04J 1/16; H04L 1/00; H04L 1/18; G01R 31/08; H04J 3/14

(52) U.S. Cl. 370/216; 370/229; 714/749

(57) ABSTRACT

Upon completion of decoding by a first decoding part 14, a first identification signal indicative of permission or inhibition of transmission of the next data is sent to a packet transmitting device.

### TECHNICAL FIELD

The present invention relates to a packet transmitting device, a packet receiving device and a packet transmission system for fast packet transmission or reception.

### TECHNICAL FIELD

Of conventional packet transmission systems, the S & W system (Stop & Wait system) is regarded as promising from the viewpoint of speedups in packet transmission.

But the system requires decoding (turbo decoding) with high error correcting power, inevitably increasing the computational complexity for decoding in the packet receiving device. Accordingly, an identification signal indicating the result of data decoding (ACK signal or NACK signal) cannot quickly be sent back to the transmitting side.

FIG. 1 is an explanatory diagram showing ARQ of a conventional packet transmission system. As is evident from FIG. 1, the packet receiving device transmits an identification signal to the packet transmitting device upon completion of decoding of data. When receiving the ACK signal, the packet transmitting device transmits the next data to the packet receiving device, whereas when receiving the NACK signal, the packet transmitting device retransmits the immediately previous data to the packet receiving device.

Since the conventional packet transmission system has such a configuration as mentioned above, no identification signal is sent to the packet transmitting device unless decoding of data is completed. Accordingly, even if it is apparent that decoding of data will not be successful (After data is decoded to some extent, it can be decides whether the decoding will be successful or not), retransmission of data cannot be requested unless time-consuming error correction or similar decoding is performed—this constitutes an obstacle to speeding up the packet transmission.

The present invention is intended to solve the above problem, and has for its object to provide a packet transmitting device, a packet receiving device and a packet transmission system that permit speedups of the packet transmission.

### DISCLOSURE OF THE INVENTION

The packet transmitting device according to the present invention is provided with first control means that receives a first identification signal sent from a packet receiving device and, when the first identification signal is indicative of permission of transmission of the next data, instructs transmitting means to transmit the next data and, when the first identification signal is indicative of inhibition of transmission of the next data, instructs the transmitting means to retransmit the data concerned.

This arrangement allows efficient transmission of data, and hence permits speedups of the packet transmission.

The packet receiving device according to the present invention is provided with identification signal generating means that: sends a first identification signal indicative of whether to permit or inhibit transmission of the next data to the packet transmitting device prior to completion of data decoding by decoding means; and sends a second identification signal indicative of whether the data decoding is successful or not to the packet transmitting device after completion of the decoding.

With this arrangement, when the likelihood of ultimate success in data decoding is slim, it is possible to request retransmission of the data concerned prior to completion of the ultimate decoding—this permits speedups of the packet transmission.

The packet transmission system according to the present invention is provided with: identification signal generating means that sends a first identification signal indicative of whether to permit or inhibit transmission of the next data to the packet transmitting device prior to completion of data decoding by decoding means, and sends a second identification signal indicative of whether the data decoding is successful or not to the packet transmitting device after completion of the decoding; and first control means that receives the first identification signal sent from the identification signal generating means and, when the first identification signal is indicative of permission of transmission of the next data, instructs transmitting means to transmit the next data and, when the first identification signal is indicative of inhibition of transmission of the next data, instructs the transmitting means to retransmit the data concerned.

With this arrangement, when the likelihood of ultimate success in data decoding is slim, it is possible to request retransmission of the data concerned prior to completion of the ultimate decoding—this permits speedups of the packet transmission.

According to an aspect of the present invention, the packet receiving device is adapted to generate the first identification signal based on the result of reception of data by receiving means.

With this scheme, when the likelihood of ultimate success in data decoding is slim, it is possible to request retransmission of the data concerned prior to completion of the ultimate decoding.

According to another aspect of the present invention, the packet receiving device is adapted to generate the first identification signal based on quality information about the data received by receiving means.

With this scheme, too, when the likelihood of ultimate success in data decoding is slim, it is possible to request retransmission of the data concerned prior to completion of the ultimate decoding.

According to another aspect of the present invention, the packet receiving device is adapted to generate the first identification signal based on the intermediate result of decoding by decoding means.

With this scheme, too, when the likelihood of ultimate success in data decoding is slim, it is possible to request retransmission of the data concerned prior to completion of the ultimate decoding.

According to another aspect of the present invention, the packet receiving device is adapted to generate the second identification signal based on ultimate result of decoding by decoding means.

This scheme ensures reception of correct data.

According to another aspect of the present invention, the packet receiving device is adapted to determine the transmission of the first identification signal in consideration of the decoding power of the decoding means.

This scheme permits reduction of the amount of storage in the packet receiving device.

According to still another aspect of the present invention, the packet transmitting device is adapted to instruct the transmission of data only when the packet receiving device is currently capable of decoding.

This scheme also permits reduction of the amount of storage in the packet receiving device.

### BRIEF DESCRIPTION OF THE DRAWINGS

FIG. 1 is an explanatory diagram showing ARQ of a conventional packet transmission system.

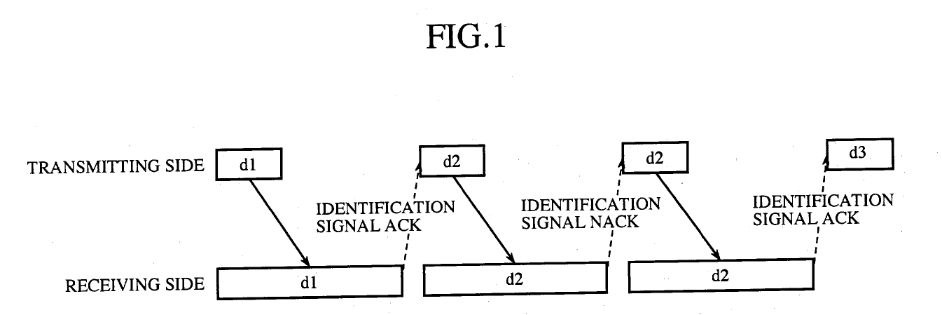

FIG. 2 is a block diagram illustrating a packet transmitting device according to Embodiment 1 of the present invention.

FIG. 3 is a block diagram illustrating a packet receiving device according to Embodiment 1 of the present invention.

FIG. 4 is a flowchart showing the contents of processing in a packet transmission system according to Embodiment 1 of the present invention.

FIG. 5 is a flowchart showing the contents of processing in a packet transmission system according to Embodiment 1 of the present invention.

FIG. 6 is an explanatory diagram showing ARQ of the packet transmission system.

FIG. 7 is a flowchart showing the contents of processing in a packet transmission system according to Embodiment 4 of the present invention.

FIG. 8 is a flowchart showing the contents of processing in a packet transmission system according to Embodiment 4 of the present invention.

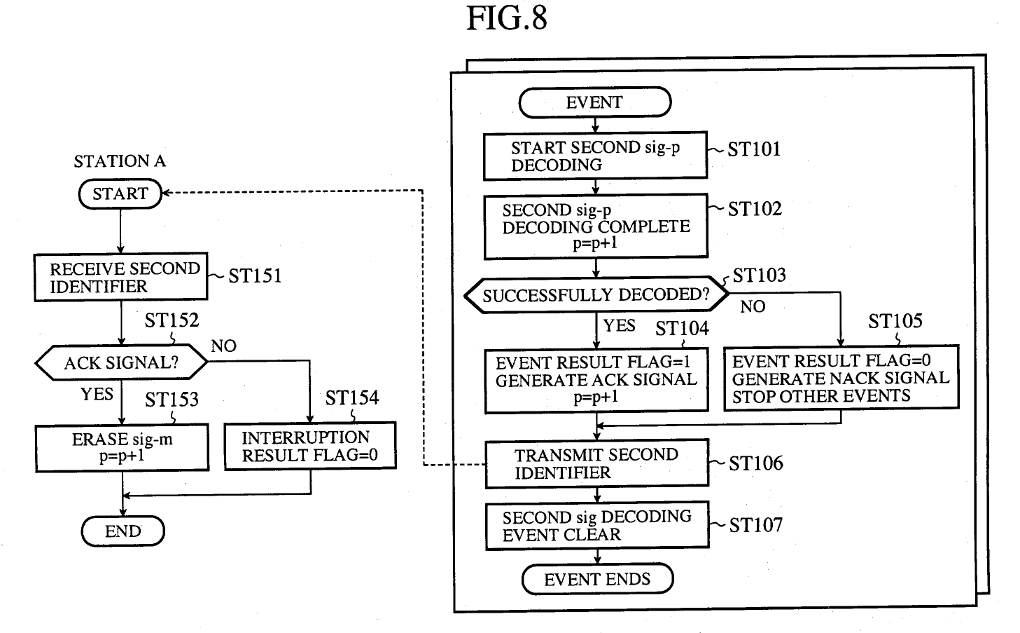

FIG. 9 is an explanatory diagram showing ARQ of the packet transmission system.

FIG. 10 is a flowchart showing the contents of processing in a packet transmission system according to Embodiment 5 of the present invention.

FIG. 11 is a flowchart showing the contents of processing in a packet transmission system according to Embodiment 5 of the present invention.

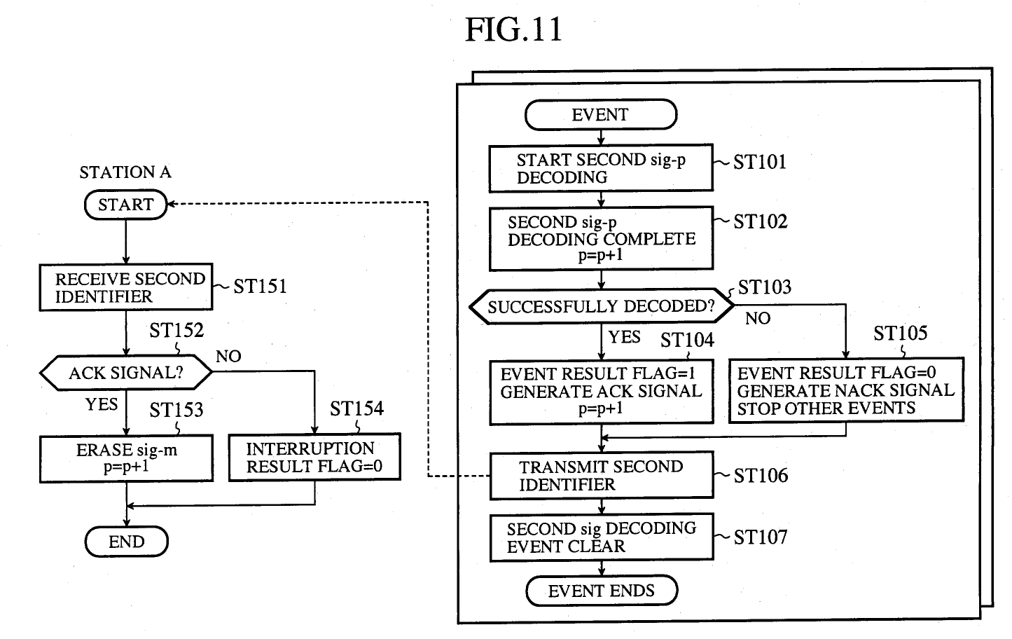

### BEST MODE FOR CARRYING OUT THE INVENTION

To facilitate a better understanding of the present invention, the best mode for carrying out the invention will hereinafter be described with reference to the accompanying drawings.

Embodiment 1

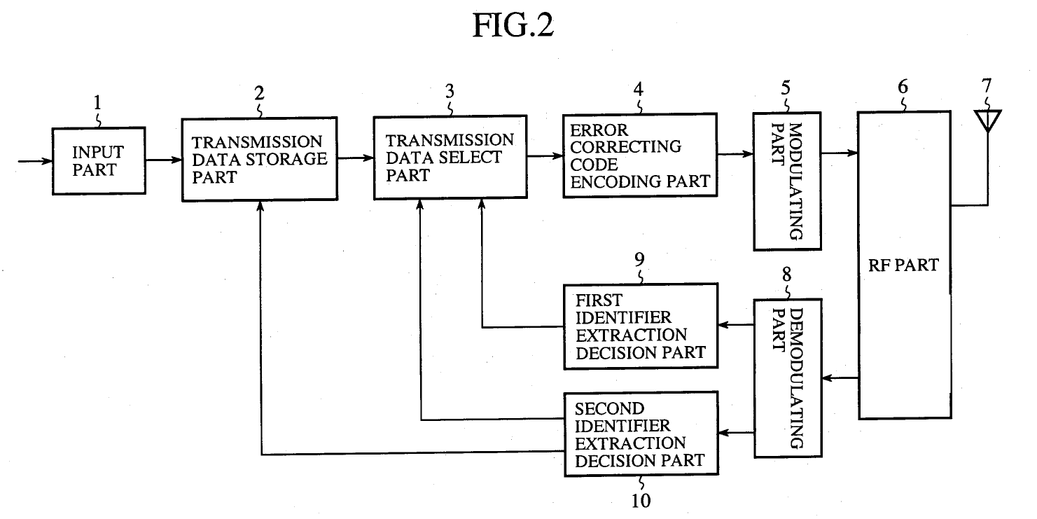

FIG. 2 is a block diagram illustrating a packet transmitting device according to Embodiment 1 of the present invention. In FIG. 2, reference numeral 1 denotes an input part for inputting data; 2 denotes a transmission data storage part for storing the data input via the input part 1; 3 denotes a transmission data select part for selecting data to be transmitted among from the pieces of data stored in the transmission data storage part 2; 4 denotes an error correcting code part for encoding the data selected by the transmission data select part 3; 5 denotes a modulating part for modulating the data encoded by the error correcting code part 4;6 denotes an RF part for transmitting the modulated wave from the modulating part 5 via an antenna 7; and 7 denotes the antenna. Incidentally, the input part 1, the transmission data storage part 2, the transmission data select part 3, the error correcting code part 4, the modulating part 5, the RF part 6 and the antenna 7 constitute transmitting means.

Reference numeral 8 denotes a demodulating part that demodulates a first or second identification signal when the RF part 6 receives it from a packet receiving device; 9 denotes a first identifier extraction decision part (first control means) that, when the first or second identification signal demodulated by the demodulating part 8 is an ACK signal, instructs the transmission data select part 3 to transmit the next data but, when the first identification signal is an NACK signal, instructs the transmission data select part 3 to retransmit the data concerned; and 10 denotes a second identifier extraction decision part (second control means) that, when the second identification signal demodulated by the demodulating part 8 is an ACK signal, instructs the transmission data storage part 2 to discard the data concerned, but when the first identification signal is an NACK signal, instructs the transmission data select part 3 to retransmit the data concerned.

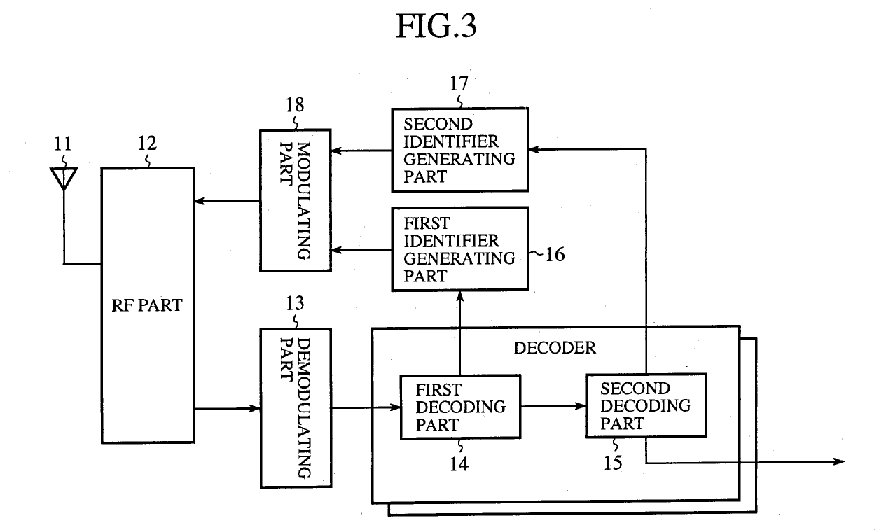

FIG. 3 is a block diagram illustrating a packet receiving device according to Embodiment 1 of the present invention. In FIG. 3, reference numeral 11 denotes an antenna 12 denotes an RF part for receiving data sent from the packet transmitting device; and 13 denotes a demodulating part for demodulating the data received by the RF part 12. Incidentally, the antenna 11, the RF part 12 and the demodulating part 13 constitute receiving means.

Reference numeral 14 denotes a first decoding part that decodes partway the data demodulated by the demodulating part 13; and 15 denotes a second decoding part that starts decoding following the first decoding part 14 and obtains the ultimate result of decoding. Incidentally, the first and second decoding parts 14 and 15 constitute a decoder (decoding means).

Reference numeral 16 denotes a first identifier generating part that generates a first identification signal based on the result of decoding by the first decoding part 14; 17 denotes a second identifier generating part that generates a second identification signal based on the result of decoding by the second decoding part 15; and 18 denotes a modulating part which modulates the first or second identification signal. Incidentally, the antenna 11, the RF part 12, the first identifier generating part 16, the second identifier generating part 17 and the modulating part 18 constitute identification signal generating means.

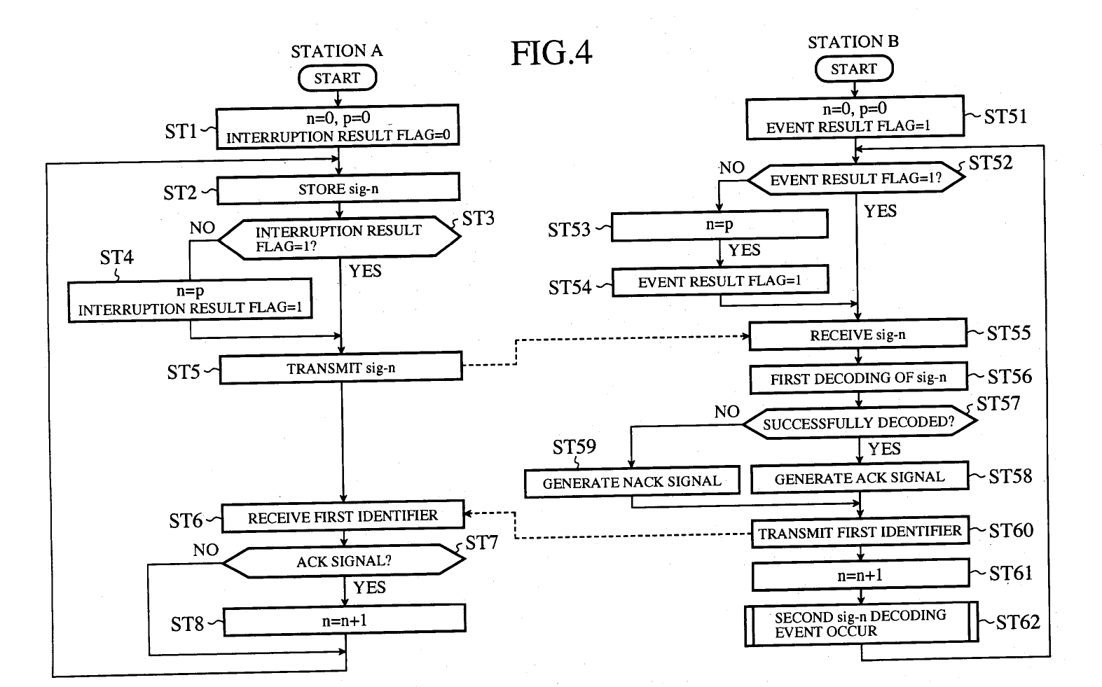

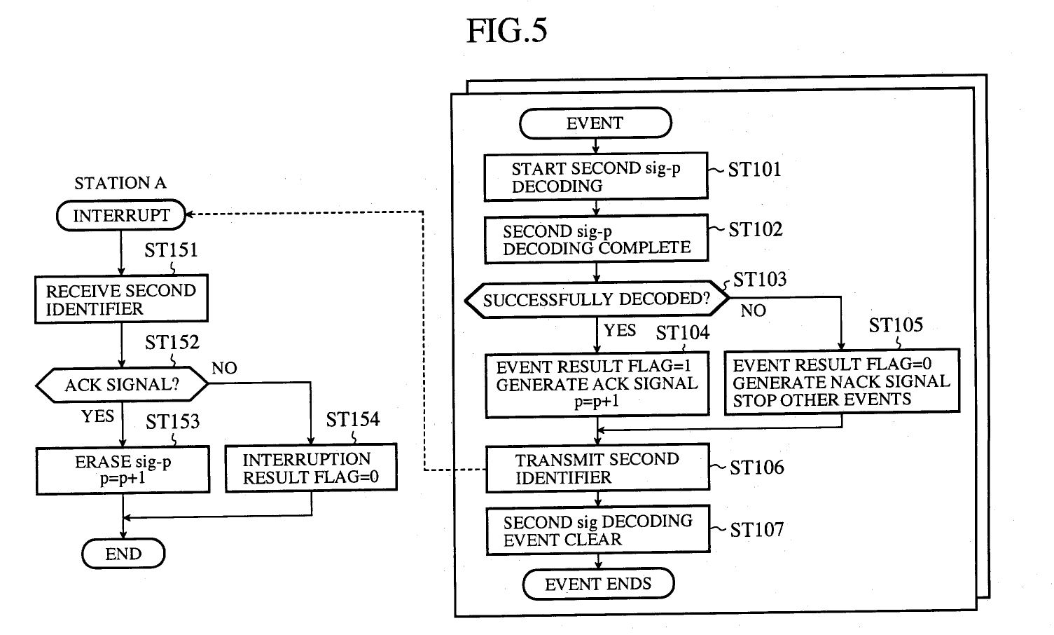

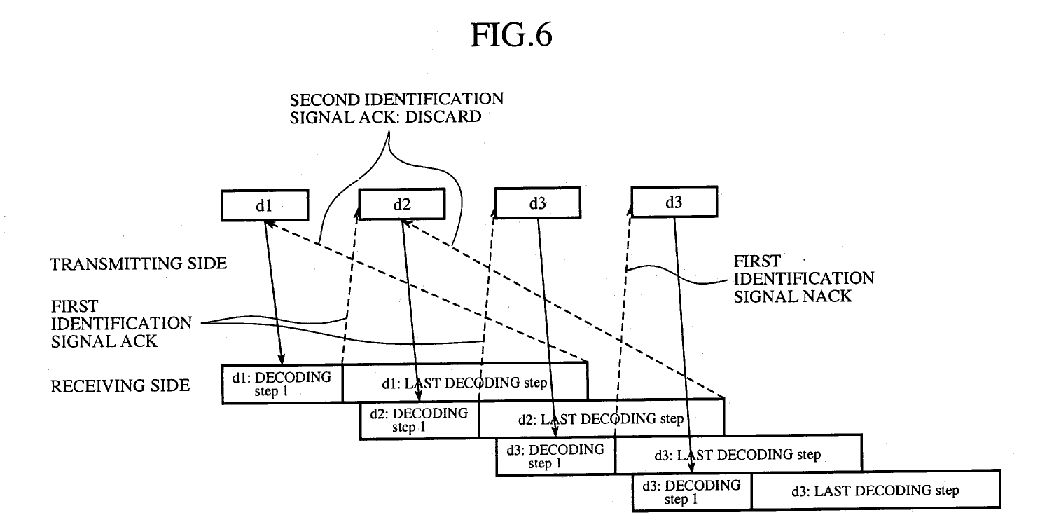

FIGS. 4 and 5 are flowcharts showing the contents of processing in the packet transmission system according to Embodiment 1 of the present invention, and FIG. 6 is an explanatory diagram showing ARQ of the packet transmission system.

Next, the operation of this embodiment will be described below.

Upon input of data to the input part 1 of the packet transmitting device, the transmission data storage part 2 stores the data (steps ST1, ST2). The transmission data select part 3 selects the data to be sent from among the pieces of data stored in the transmission data storage part 2. For convenience of explanation, let it be assumed that data sig-n is selected.

The error correcting code part 4 encodes the data selected by the transmission select part 3, then the modulating part 5 modes the data encoded by the error correcting code part 4, and the RF part 6 radios the modulated wave from the modulating part 5 via the antenna 7 (steps ST3 to ST5).

On the other hand, the RF part 12 of the packet receiving device receives the data sent from the packet transmitting device, and the demodulating part 13 demodulates the data received by the RF part 12 (step ST55). For the purpose of generating a correct identification signal, the packet receiving device performs initialization of various variables prior to receiving data (steps ST51 to ST54).

The first decoding part 14 decodes partway the data demodulated by the demodulating part 13 (step ST56).

The first identifier generating part 14 refers to a check bit such as CRC to decide whether the decoding carried out partway is successful (step ST57). When the decoding is successful, the first identifier generating part generates an ACK signal as the first identification signal as depicted in FIG. 6 (step ST58). On the other hand, when the decoding is unsuccessful, the first identifier generating part generates an NACK signal as the first identification signal (step ST59) since further decoding is meaningless.

While in the above the first identifier generating part is described to refer to the check bit like CRC, the invention is not limited specifically thereto but may also be adapted to refer to, for instance, the result of decoding of TFCI (Transport Format combination Indicator) transmitting channel multiplex information by 3GPP (3^{rd} Generation Partnership Project) specification, or the result of reception of a known pattern.

The modulating part 18 modulates the first identification signal generated by the first identifier generating part 16, and the RF part 12 transmits the modulated wave from the modulating part 18 via the antenna 11 (step ST60).

The demodulating part 8 of the packet receiving device demodulates the first identification signal that the RF part 6 receives from the packet receiving device (step ST6).

The first identifier extraction decision part 9 decides whether the first identification signal demodulated by the demodulating part 8 is an ACK signal or NACK signal (step ST7).

When the first identification signal is an ACK signal, the first identifier extraction decision part instructs the transmission data select part 3 to transmit the next data (step ST8). On the other had, when the first identification signal is an NACK signal, the first identifier extraction decision part instructs the transmission data select part 3 to retransmit the data concerned.

Incidentally, in the case where plural decoders are prepared which constitute the first decoding part 14 and the second decoding part 15 in the packet receiving device (three decoders in the example of FIG. 6), assuming that a first one of the decoders performs the above-mentioned decoding, the packet transmitting device transmits the next data or the immediately previous data to an (i+1)-th decoder. In the FIG. 6 example, decoding of data d3 is unsuccessful and is retransmitted.

When the first identifier extraction decision part 9 generates and transmits the first identification signal, the second decoding part 15 of the packet receiving device resumes decoding following the first decoding part 14, obtaining the ultimate result of decoding (steps ST61, ST62, ST101, ST102).

The second identifier generating part 17 decides whether the ultimate decoding is successful or not (step ST103). When the decoding is successful, the second identifier generating part generates an ACK signal as the second identification signal as shown in FIG. 6 (step ST104). On the other hand, when the decoding is unsuccessful, the second identifier generating part generates an NACK signal as the second identification signal (step ST105).

The modulating part 18 modulates the second identification signal generated by the second identifier generating part 17, and the RF part 12 transmits the modulated wave from the modulating part 18 via the antenna 11 (steps ST106, ST107).

The demodulating part 8 of the packet transmitting device demodulates the second identification signal the RF part 6 receives from the packet receiving device (step ST151).

The second identifier extraction decision part 10 decides whether the second identification signal demodulated by the demodulating part 8 is an ACK signal or NACK signal (step ST152).

When the second identification signal is an ACK signal, the second identifier extraction decision part instructs the transmission data storage part 2 to discard the data concerned (step ST153). On the other hand, when the second identification signal is an NACK signal, the second identifier extraction decision part instructs the transmission data select part 3 to retransmit the data concerned (step ST154).

As is evident from the above, according to Embodiment 1, upon completion of decoding by the first decoding part, the first identification signal indicating whether to permit the transmission of the next data is sent to the packet transmitting device; hence, when the whole decoding is very likely to fail, it is possible to request retransmission of the data concerned before the second decoding part 15 starts decoding. This provides increased packet transmission efficiency and hence allows speedups of packet transmission.

Embodiment 2

While Embodiment 1 has been described to generate the first identification signal based on the intermediate result of decoding, the first identification signal may be generated based on the result of reception of data by the RF part 12.

That is, provision is made to generate the ACK signal or NACK signal, depending on whether the RF part 12 normally receives data or not.

With this scheme, when data is not normally received, it is possible to request retransmission of data prior to starting subsequent decoding.

Embodiment 3

While Embodiment 1 has been described to generate the first identification signal based on the intermediate result of decoding, the first identification signal may be generated based on quality information about the data received by the RF part 12.

Provision is made to generate the First identification signal, for example, by referring to the correlation value of received data obtained by the execution of de-spreading, the receiving field intensity, SIR, or the distance from ideal amplitude/ideal phase at the time of multilevel modulation.

By referring to the data quality information as mentioned above, it is possible, as is the case with Embodiment 1, to decide the likelihood of success in the ultimate decoding prior to proceeding to the ultimate decoding.

Embodiment 4

While Embodiment 1 has been described to generate the first identification signal based on the intermediate result of decoding, provision may be made to determine the transmission of the first identification signal taking into consideration of the decoding power of the decoders forming the first and second decoding parts 14 and 15.

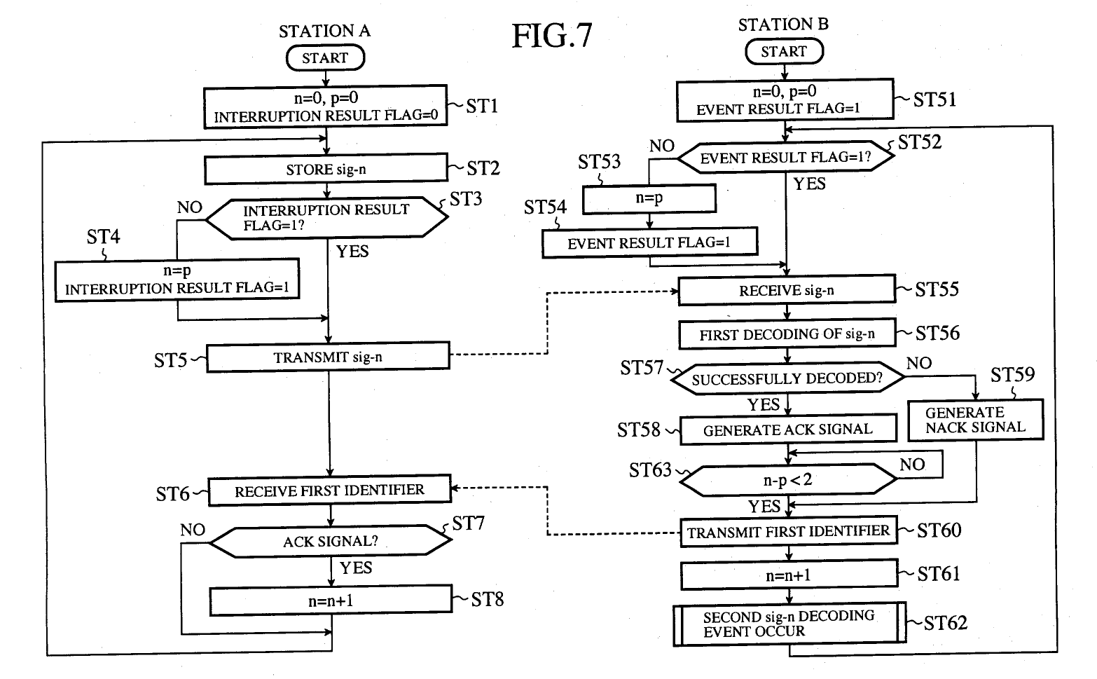

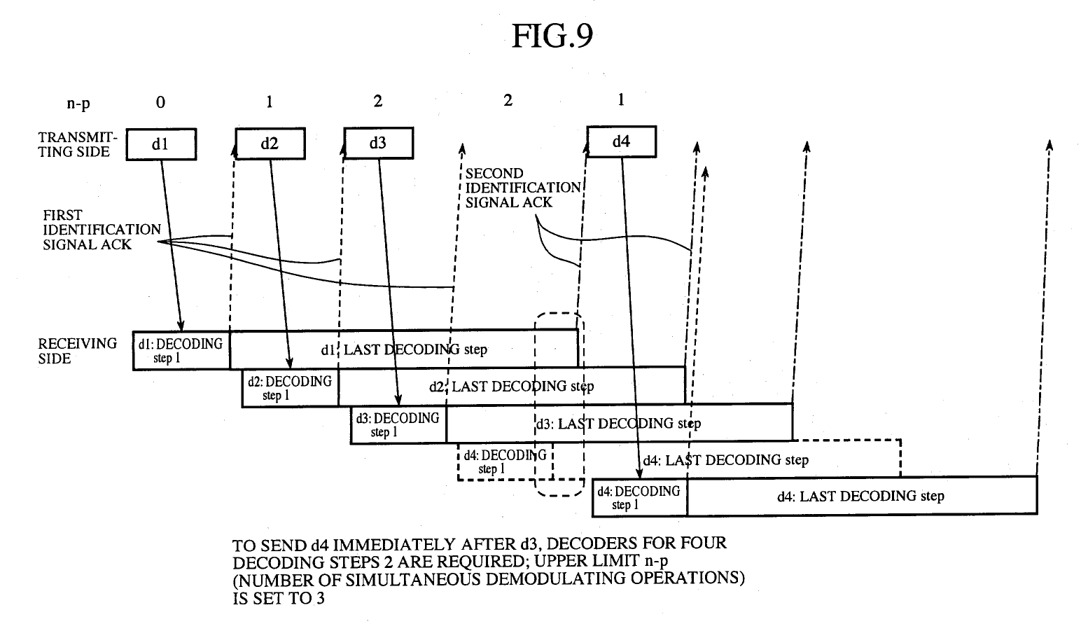

For instance, when plural decoders are prepared, it is decided whether there is present a decoder currently in OFF state (step ST63 in FIG. 7), and only when such an OFF-state decoder, the first identification signal is sent to the packet transmitting device (see FIG. 9).

This scheme permits reduction of the amount of storage in the packet receiving device.

Embodiment 5

While Embodiment 1 has been described to generate the first identification signal based on the intermediate result of decoding, provision may be made to instruct the transmission of data only when the packet receiving device is currently capable of decoding.

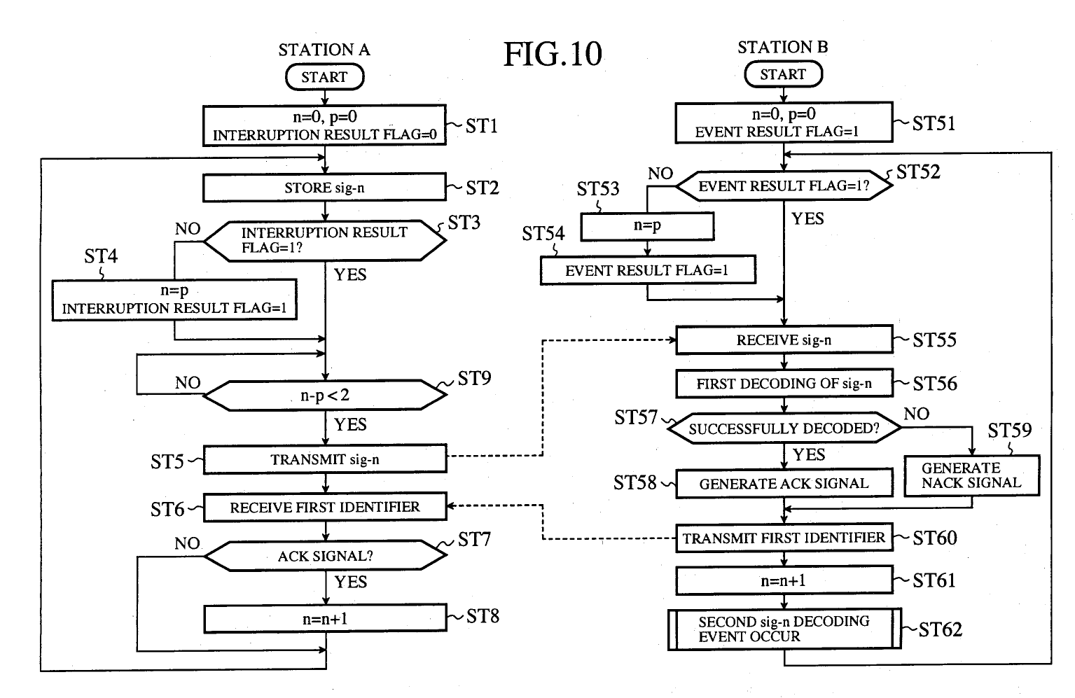

For instance, when plural decoders are prepared, it is decided whether there is present a decoder currently in OFF state (step ST9 in FIG. 10), and only when such an OFF-state decoder, the transmission of data is instructed.

This scheme also permits reduction of the amount of storage in the packet receiving device.

Industrial Applicability

As described above, the packet transmission system according to the present invention and the associated devices effectively allow reduction of decoding of no use and hence permit speedups of the packet transmission.

1. A packet transmitting device provided with: transmitting means that transmits data to a packet receiving device; first control means that receives a first identification signal sent from said packet receiving device and, when the first identification signal is indicative of permission of transmission of the next data, instructs said transmitting means to transmit the next data and, when the first identification signal is indicative of inhibition of transmission of the next data, instructs said transmitting means to retransmit the data concerned; and second control means that receives a second identification signal sent from said packet receiving device and, when the second identification signal is indicative of success in decoding, discards the data concerned and, when the second identification signal is indicative of failure in decoding, instructs said transmitting means to retransmit the data concerned.

2. A packet receiving device provided with: receiving means that receives data sent from a packet transmitting device; decoding means that decodes the data received by said receiving means; and identification signal generating means that sends a first identification signal indicative of whether to permit or inhibit transmission of the next data to said packet transmitting device prior to completion of data decoding by said decoding means and sends a second identification signal indicative of whether the data decoding by said decoding means is successful or not to said packet transmitting device after completion of the decoding.

3. A packet transmission system provided with: transmitting means that transmits data; receiving means that receives the data sent from said transmitting means; decoding means that decoding the data received by said receiving means; identification signal generating means that sends a first identification signal indicative of whether to permit or inhibit transmission of the next data to the packet transmitting device prior to completion of data decoding by said decoding means, and sends a second identification signal indicative of whether the data decoding by said decoding means is successful or not to the packet transmitting device after completion of the decoding; first control means that receives the first identification signal sent from said identification signal generating means and, when the first identification signal is indicative of permission of transmission of he next data, instructs said transmitting means to transmit the next data and, when the first identification signal is indicative of inhibition of transmission of the next data, instructs said transmitting means to retransmit the data concerned; and second control means that receives a second identification signal sent from said identification signal generating means and, when the second identification signal is indicative of a success in decoding, discards the data concerned and, when the second identification signal is indicative of a failure in decoding, instructs said transmitting means to retransmit the data concerned.

4. The packet receiving device as claimed in claim 2, characterized in that the identification signal generating means generates the first identification signal based on the result of reception of the data by the receiving means.

5. The packet receiving device as claimed in claim 2, characterized in that the identification signal generating means generates the first identification signal based on quality information about the data received by the receiving means.

6. The packet receiving device as claimed in claim 2, characterized in that the identification signal generating means generates the first identification signal based on the intermediate result of decoding by the decoding means.

7. The packet receiving device as claimed in claim 2, wherein the identification signal generating means generates the second identification signal based on the ultimate result of decoding by the decoding means.

8. The packet receiving device as claimed in claim 2, characterized in that the identification signal generating means determines the transmission of the first identification signal in consideration of the decoding power of the decoding means.

9. The packet transmitting device as claimed in claim 1, characterized in that the first control means instructs the transmission of data only when the packet receiving device is currently capable of decoding.
